(19) United States
(12) Patent Application Publication
(10) Pub. No.: US 2026/0323781 A1
(43) Pub. Date: Oct. 15, 2026

(54) CERAMIC HEATER

(71) Applicant: NGK Corporation, Nagoya-shi (JP)

(72) Inventor: Yutaka UNNO, Handa-shi (JP)

(21) Appl. No.: 19/690,301

(22) Filed: May 28, 2026

Related U.S. Application Data
(63) Continuation of application No. PCT/JP2024/002253, filed on Jan. 25, 2024.

(51) Int. Cl. H05B 3/18; G01K 1/14; G01K 7/02; H05B 3/03; H10P 72/72; H10P 72/76

(52) U.S. Cl. CPC H05B 3/18; G01K 1/14; G01K 7/02; H05B 3/03; H10P 72/722; H10P 72/7616

(57) ABSTRACT

Provided is a ceramic heater including a disk-shaped ceramic plate having a diameter of 220 mm or larger and having a first surface and a second surface; at least one heater circuit embedded in the ceramic plate; four or more bottomed holes provided to start from the second surface in a thickness direction, within a central region having a radius of 25 mm from a center of the ceramic plate; and at least one pair of heater terminals inserted into at least two of the bottomed holes and electrically connected to the heater circuit. The heater circuit includes a heater main portion disposed to be capable of heating a region outside the central region and including a resistive heating element such as a coil; and a heater element wire portion disposed to be capable of heating the central region and composed of a non-coiled wire-shaped resistive heating element.

### CROSS-REFERENCE TO RELATED APPLICATION

This application is a continuation application of PCT/JP2024/002253 filed Jan. 25, 2024, the entire contents of which are incorporated herein by reference.

### BACKGROUND OF THE INVENTION

### 1. Field of the Invention

The present disclosure relates to a ceramic heater.

### 2. Description of the Related Art

In a film formation device for semiconductor manufacturing processes, a ceramic heater is used as a supporting stage for uniformly controlling the temperature of a wafer. Widely used as such a ceramic heater is one including: a ceramic plate on which the wafer is to be placed; and a circular cylindrical ceramic shaft attached to the ceramic plate. Further, as a ceramic heater, a multi-zone ceramic heater having a plurality of heating zones is also known.

Patent Literature 1 (JP2022-120251A) discloses a wafer support stage including a ceramic base body having a wafer placement surface and a plurality of heaters embedded in the ceramic base body. The ceramic base body includes a first heater formation surface, a second heater formation surface, and a third heater formation surface in the stated order from a wafer placement surface toward the opposite surface of the wafer placement surface. The plurality of heaters include a first heater provided on the first heater formation surface, a second heater provided on the second heater formation surface, and a third heater provided on the third heater formation surface. The first heater is provided so as to be positioned at the center of the ceramic base body. The second heater is provided so as to be positioned at the outer perimeter of the first heater. The third heater is provided so as to overlap with the second heater while the third heater formation surface is provided in each of a plurality of zones divided by line segments extending in the radial direction. The wafer support stage is configured so that a jumper linearly extending from a central part of the ceramic base body is connected to a coil portion of the heaters.

### CITATION LIST

### Patent Literature

Patent Literature 1: JP2022-120251A

### SUMMARY OF THE INVENTION

Ceramic heaters are required to have little temperature difference (i.e., temperature uniformity) within the plane on which a wafer is placed. In particular, because processes are getting finer and more highly integrated in recent years, ceramic heaters are required to have even higher temperature uniformity. From this viewpoint, it is desired to minimize the temperature difference between the location where a resistive heating element is provided and other locations. For this purpose, it is desirable to arrange the resistive heating elements throughout the entire region of the ceramic heater. Meanwhile, multi-zone heaters (e.g., having two or more zones) have, due to the structure thereof, an increase in the number of holes for inserting heater terminals and the like in accordance with an increase in the number of zones. For example, in a ceramic heater having a ceramic shaft arranged at the center of a ceramic plate, because a terminal hole, a thermocouple hole, a vacuum chuck hole, and the like are concentrated in a plate central part, it is difficult to arrange resistive heating elements throughout the plate central part. For this reason, a cool spot heated insufficiently may occur in a section where it is impossible to arrange the resistive heating elements, which may cause the problem of degraded heater temperature uniformity.

The present inventors have found that by disposing, as a part of a heater circuit, a non-coiled wire-shaped resistive heating element within a central region having a radius of 25 mm from the center of a ceramic plate, instead of a normal resistive heating element such as a coil, it is possible to inhibit the occurrence of a cool spot even in a plate central region where four or more bottomed holes are present, thereby improving temperature uniformity.

Thus, it is an object of the present invention to provide a ceramic heater that can inhibit the occurrence of a cool spot even in a plate central region where four or more bottomed holes are present, thereby improving temperature uniformity.

The present disclosure provides the following aspects.

### [Aspect 1]

A ceramic heater comprising:
a disk-shaped ceramic plate having a diameter of 220 mm or larger and having a first surface on which a wafer is to be placed and a second surface opposite the first surface;
at least one heater circuit embedded in the ceramic plate;
four or more bottomed holes provided from the second surface in a thickness direction of the ceramic plate, so that at least a part of each of the bottomed holes is positioned within a central region having a radius of 25 mm from a center of the ceramic plate; and
at least one pair of heater terminals inserted into at least two of the bottomed holes and electrically connected to the heater circuit, wherein
the heater circuit includes:
   a heater main portion disposed so as to be capable of heating a region outside the central region and including a resistive heating element in at least one form selected from the group consisting of a coil, a linear zigzag structure, a printed pattern, a ribbon, and a mesh; and
   a heater element wire portion disposed so as to be capable of heating the central region and composed of a non-coiled wire-shaped resistive heating element, the heater element wire portion being disposed, in a planar perspective view, so as to start from one of the heater terminals and to reach one end of the heater main portion while, within the central region, avoiding or bypassing all the bottomed holes other than the bottomed hole in which the one of the heater terminals is positioned.

### [Aspect 2]

The ceramic heater according to aspect 1, wherein the wire-shaped resistive heating element has a diameter in a range of 0.3 mm to 0.8 mm.

### [Aspect 3]

The ceramic heater according to aspect 1 or 2, wherein, in a planar view of the ceramic plate, the ceramic plate includes an inside zone defined as a circular region within a prescribed distance from the center of the ceramic plate; and an outside zone defined as an annular region outside the inside zone,
wherein the heater circuit includes:
   an inside zone heater circuit embedded in the inside zone of the ceramic plate;
   an outside zone heater circuit embedded in the outside zone of the ceramic plate; and
   a pair of jumpers that are embedded in the inside zone of the ceramic plate so as not to be in contact with the inside zone heater circuit and that are electrically connected to the outside zone heater circuit, and
wherein the inside zone heater circuit includes the heater main portion and the heater element wire portion, the outside zone heater circuit includes the heater main portion, and the heater element wire portion is disposed, in a planar perspective view, so as not to intersect the pair of jumpers.

### [Aspect 4]

The ceramic heater according to any one of aspects 1 to 3, wherein the ceramic plate contains aluminum nitride or aluminum oxide.

### [Aspect 5]

The ceramic heater according to any one of aspects 1 to 4, further comprising a ceramic shaft that has a circular cylindrical shape including an internal space and is attached to the second surface of the ceramic plate.

### [Aspect 6]

The ceramic heater according to any one of aspects 1 to 5, wherein the resistive heating element contains at least one selected from the group consisting of tungsten, molybdenum, a tungsten-molybdenum alloy, tungsten carbide, a tungsten carbide-titanium nitride composite material, a tungsten carbide-aluminum oxide composite material, and niobium.

### [Aspect 7]

The ceramic heater according to any one of aspects 1 to 6, wherein the heater main portion and the heater element wire portion are configured as a continuous integrally-formed resistive heating element.

### [Aspect 8]

The ceramic heater according to any one of aspects 1 to 7, wherein the heater main portion and the heater element wire portion are separate resistive heating elements and are connected to each other via a connection terminal.

### [Aspect 9]

The ceramic heater according to aspect 8, wherein the connection terminal is arranged within the central region of the ceramic plate.

### [Aspect 10]

The ceramic heater according to any one of aspects 1 to 9, wherein the connection terminal is a conductive member having two through holes with different diameters into which resistive heating elements having different wire diameters are connectable.

### [Aspect 11]

The ceramic heater according to any one of aspects 1 to 10, further comprising, in the ceramic plate, an internal electrode being an RF electrode and/or an ESC electrode, wherein the RF terminal and/or the ESC terminal is inserted into at least one of the bottomed holes other than the bottomed holes into which the pair of heater terminals are inserted.

### [Aspect 12]

The ceramic heater according to any one of aspects 1 to 11, wherein a thermocouple is inserted into one of the bottomed holes other than the bottomed holes into which the pair of heater terminals are inserted.

### [Aspect 13]

The ceramic heater according to any one of aspects 3 to 12, wherein the inside zone heater circuit and the outside zone heater circuit are arranged on the same plane in a cross-sectional view.

### [Aspect 14]

The ceramic heater according to any one of aspects 3 to 12, wherein the inside zone heater circuit and the outside zone heater circuit are arranged on different planes in a cross-sectional view.

### BRIEF DESCRIPTION OF THE DRAWINGS

FIG. 1 is a perspective cross-sectional view schematically showing an example (corresponding to Example 1) of a ceramic heater according to the present invention. For the sake of convenience in the descriptions, jumpers 14c are depicted in a position slightly lower than the actual position, in order to illustrate, in an easy-to-understand manner, the configurations of an inside zone heater circuit 14a and the jumpers 14c which are actually positioned at the same height.

FIG. 2 is a top view schematically showing the ceramic heater shown in FIG. 1.

FIG. 3 is a plan view schematically showing an arrangement of a heater circuit in a central region and the vicinity thereof with regard to the ceramic plate shown in FIG. 1.

FIG. 4 is a plan view schematically showing a configuration of the heater circuit shown in FIG. 3.

FIG. 5 is a plan view schematically showing the connection terminal shown in FIG. 4.

FIG. 6 is a perspective cross-sectional view schematically showing another example of a ceramic heater according to the present invention.

FIG. 7 is a perspective cross-sectional view schematically showing an example (corresponding to Example 2 (a comparison example)) of a ceramic heater that is not of the present invention.

FIG. 8 is a plan view schematically showing an arrangement of a heater circuit in a central region and the vicinity thereof with regard to the ceramic heater shown in FIG. 7.

FIG. 9 is a temperature distribution map of the ceramic plate measured of Example 1.

FIG. 10 is a temperature distribution map of the ceramic plate measured of Example 2 (the comparison example).

### DETAILED DESCRIPTION OF THE INVENTION

A ceramic heater according to the present invention is a stage made of ceramics for supporting a wafer in a semiconductor manufacturing device. Typically, the ceramic heater according to the present invention may be a ceramic heater for a semiconductor film formation device. Typical examples of film formation devices include Chemical Vapor Deposition (CVD) devices (e.g., thermal CVD devices, plasma CVD devices, photo-assisted CVD devices, and MOCVD devices) and Physical Vapor Deposition (PVD) devices.

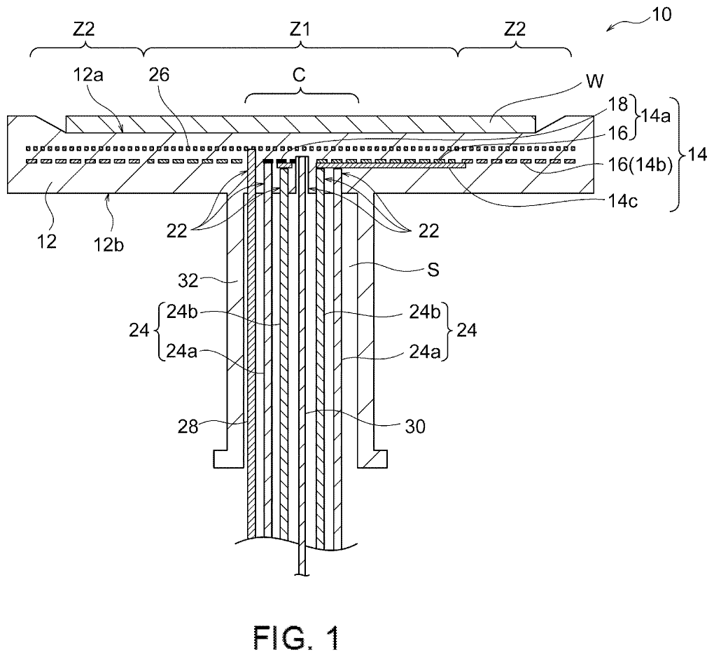

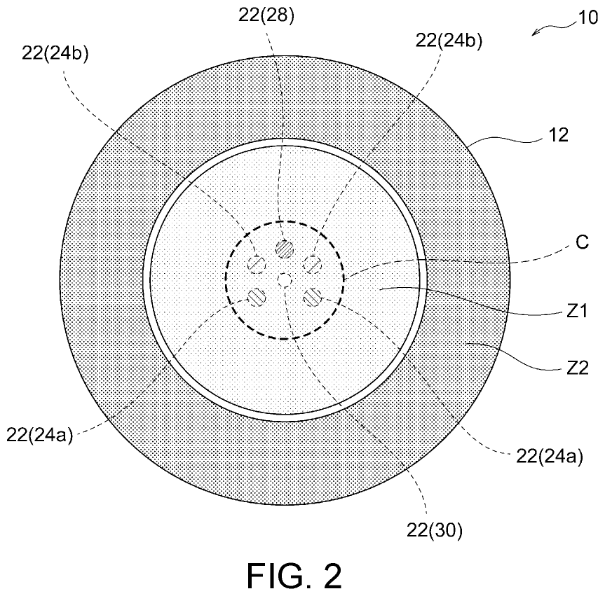

FIGS. 1 and 2 illustrate one aspect of a ceramic heater. A ceramic heater 10 shown in FIGS. 1 and 2 includes a ceramic plate 12, at least one heater circuit 14, four or more bottomed holes 22, and at least one pair of heater terminals 24. The ceramic plate 12 has a disk shape having a diameter of 220 mm or larger and has a first surface 12a on which a wafer W is to be placed and a second surface 12b opposite the first surface 12a. The heater circuit 14 is embedded in the ceramic plate 12 and may be, for example, a multi-zone heater (e.g., a two-zone heater) including an inside zone heater circuit 14a and an outside zone heater circuit 14b. The bottomed holes 22 are provided from the second surface 12b in the thickness direction of the ceramic plate 12, so that at least a part of each of the bottomed holes 22 is positioned within a central region C having a radius of 25 mm from the center of the ceramic plate 12. At least one pair of heater terminals 24 (i.e., at least two heater terminals 24) are inserted into at least two of the bottomed holes 22 and are electrically connected to the heater circuit 14. The heater circuit 14 includes a heater main portion 16 and a heater element wire portion 18. The heater main portion 16 includes a resistive heating element in at least one form selected from the group consisting of a coil, a linear zigzag structure, a printed pattern, a ribbon, and a mesh and is disposed so as to be capable of heating a region outside the central region C. Meanwhile, the heater element wire portion 18 is composed of a non-coiled wire-shaped resistive heating element and is disposed so as to be capable of heating the central region C. In a planar perspective view of the ceramic plate 12, the heater element wire portion 18 is disposed so as to start from one of the heater terminals 24 and to reach one end of the heater main portion 16 while, within the central region C, avoiding or bypassing all the bottomed holes 22 other than the bottomed hole 22 in which the one of the heater terminals 24 is positioned. In this manner, by disposing, as a part of the heater circuit, a non-coiled wire-shaped resistive heating element within the central region C having a radius of 25 mm from the center of the ceramic plate 12, instead of a normal resistive heating element such as a coil, it is possible to inhibit the occurrence of a cool spot even in the plate central region C where the four or more bottomed holes 22 are present, thereby improving temperature uniformity.

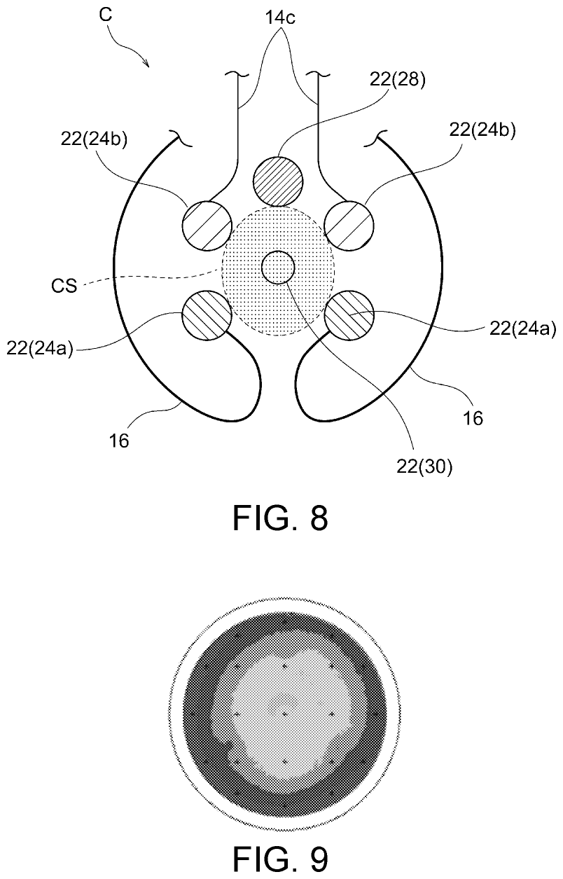

As mentioned earlier, ceramic heaters are required to have even higher temperature uniformity because processes are getting finer and more highly integrated in recent years. For this purpose, it is desirable to arrange resistive heating elements throughout the entire region of a ceramic heater. Meanwhile, multi-zone heaters (e.g., having two or more zones) have, due to the structure thereof, an increase in the number of holes for inserting heater terminals and the like in accordance with an increase in the number of zones. For example, in a ceramic heater having a ceramic shaft disposed at the center of a ceramic plate, because a terminal hole, a thermocouple hole, a vacuum chuck hole, and the like are concentrated in a plate central part, it is difficult to arrange resistive heating elements throughout the plate central part. For this reason, as shown in FIG. 8, a cool spot CS heated insufficiently may occur in a section where it is impossible to arrange the resistive heating elements, which may cause the problem of degraded heater temperature uniformity. In addition, due to such a cool spot in a central part of the ceramic plate, a center-cool temperature distribution profile may be exhibited in which the temperature locally decreases at the center of the plate central part. Thus, a problem may arise in which a thermal stress concentration is caused in a section where terminal holes are concentrated, which may lead to damaging the heater. These problems are successfully resolved or reduced by the present invention. That is, in the present invention, a non-coiled wire-shaped resistive heating element (the heater element wire portion 18) is adopted as a part of the heater circuit 14 in the central region C of the ceramic plate 12, which was regarded as a terminal-dense region where it has conventionally been difficult to arrange a resistive heating element. With the above configuration, it is possible to arrange the heater circuit 14 (in particular, the heater element wire portion 18) so as to reach the one end of the heater main portion 16 while avoiding or bypassing all the bottomed holes 22 other than the bottomed hole 22 being a starting point. Consequently, even in the central region C, it is possible to implement desired heating while inhibiting the occurrence of a cool spot. As a result, it is possible to improve temperature uniformity of the ceramic plate 12.

In view of providing a principal section (i.e., a ceramic base body) other than embedded members such as the heater circuit 14, with excellent thermal conductivity, high electric insulation, a thermal expansion characteristic close to that of silicon, and the like, the ceramic plate 12 preferably contains aluminum nitride or aluminum oxide and more preferably contains aluminum nitride.

The ceramic plate 12 has a disk shape. However, the shape of the disk-shaped ceramic plate 12 does not necessarily need to be a perfect circle in a planar view and may be an imperfect circle having a portion cut away, such as an orientation flat. The diameter of the ceramic plate 12 is 220 mm or larger and is typically in the range of 220 mm to 450 mm and, especially for a 300-mm silicon wafer, is typically in the range of 320 mm to 380 mm. Further, the thickness of the ceramic plate 12 is typically in the range of 10 mm to 25 mm.

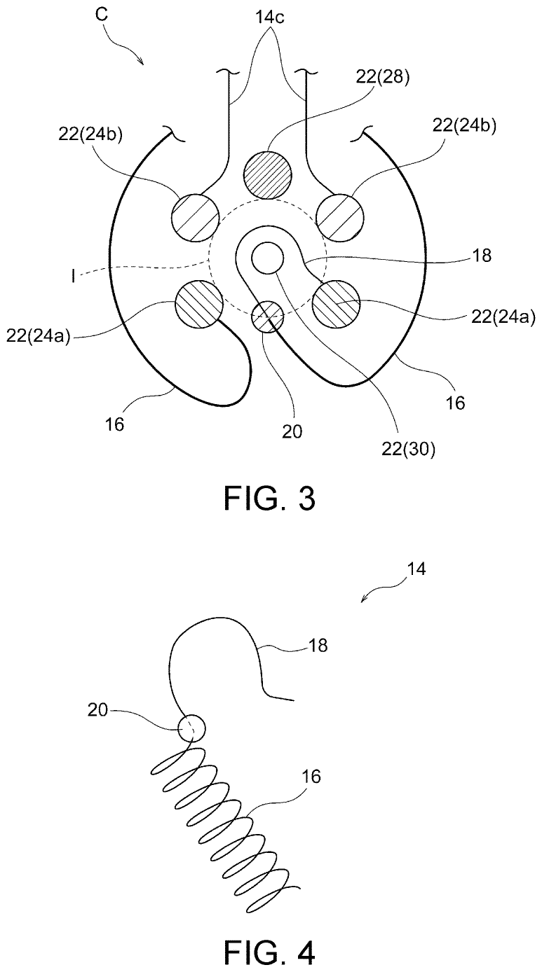

As shown in FIGS. 3 and 4, the heater circuit 14 includes the heater main portion 16 disposed so as to be capable of heating a region outside the central region C of the ceramic plate 12 and the heater element wire portion 18 disposed so as to be capable of heating the central region C of the ceramic plate 12.

The heater main portion 16 includes the resistive heating element in at least one form selected from the group consisting of a coil, a linear zigzag structure, a printed pattern, a ribbon, and a mesh. The coil has a structure in which a resistive heating wire is three-dimensionally wound. As another example, the linear zigzag structure has a structure in which a resistive heating wire is two-dimensionally folded back and forth within a plane. The printed pattern is not particularly limited, but typically has a pattern in which a belt-like line of a resistive heating element layer repeatedly alternates advancing straight and bending (in a zigzag formation, for example).

The heater element wire portion 18 is composed of the non-coiled wire-shaped resistive heating element (i.e., not wound). In a planar perspective view, the heater element wire portion 18 is disposed, as shown in FIG. 3, so as to start from one of the heater terminals 24 and to reach the one end of the heater main portion 16 while, in the central region C, avoiding or bypassing all the bottomed holes 22 other than the bottomed hole 22 in which the one of the heater terminals 24 is positioned. The shape of the heater element wire portion 18 in a planar view is typically a meandering shape (involving a curved line) as shown in FIG. 3, but may be a combination of a curved portion and a linear portion or may be a combination of a plurality of linear portions. For example, as shown in FIG. 3, in order to uniformly heat the central region C, it is desirable to define an inscribed circle I in contact with all of the bottomed holes 22 (the five bottomed holes 22 in the drawing) located at positions other than the center of the central region C, and to arrange the heater element wire portion 18 so as to extend approximately one turn (preferably while meandering) in an annular region between the inscribed circle I and the bottomed hole 22 positioned at the center of the central region C. Examples of the bottomed holes 22 other than the bottomed hole 22 in which the one of the heater terminals 24 is positioned include: a bottomed hole 22 in which another heater terminal 24 is positioned, a bottomed hole 22 in which an RF terminal 28 is positioned, and a bottomed hole 22 in which a thermocouple 30 is positioned. The diameter of the wire-shaped resistive heating element is preferably in the range of 0.3 mm to 0.8 mm and more preferably in the range of 0.3 mm to 0.5 mm.

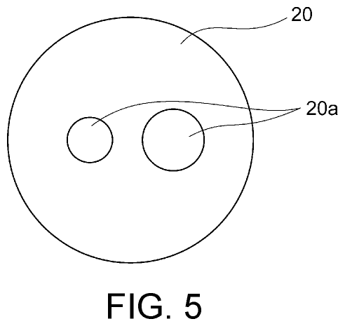

The heater main portion 16 and the heater element wire portion 18 may be configured as a continuous integrally-formed resistive heating element. Alternatively, the heater main portion 16 and the heater element wire portion 18 may be separate resistive heating elements that are connected to each other via a connection terminal 20, as shown in FIGS. 3 and 4. In that situation, it is desirable to arrange the connection terminal 20 in the central region C of the ceramic plate 12. Accordingly, by using the connection terminal 20, it is possible to connect together resistive heating elements with different wire diameters. In other words, this aspect is advantageous when the wire diameter of the heater main portion 16 is different from the wire diameter of the heater element wire portion 18. As shown in FIG. 5, it is desirable when the connection terminal 20 is a conductive member having two through holes 20a with different diameters into which resistive heating elements having different wire diameters are connectable. With this configuration, it is possible to secure the electric connection of the heater main portion 16 and the heater element wire portion 18, by inserting the heater main portion 16 and the heater element wire portion 18 into the two through holes 20a, respectively, and crimping and/or stabilizing the two. Although not particularly limited, the shape of the connection terminal 20 may be spherical, for example; however, when the wire diameter of the heater main portion 16 (e.g., a coil) is equal to the wire diameter of the heater element wire portion 18, the connection terminal 20 is not necessary.

It is desirable that the resistive heating element constituting the heater circuit 14 (i.e., the heater main portion 16, the heater element wire portion 18, and the connection terminal 20) contain at least one selected from the group consisting of tungsten, molybdenum, a tungsten-molybdenum alloy, tungsten carbide, a tungsten carbide-titanium nitride composite material, a tungsten carbide-aluminum oxide composite material, and niobium.

In an example of a multi-zone heater (e.g., a two-zone heater), the ceramic plate 12 may include an inside zone Z1 and an outside zone Z2, in a planar view. The inside zone Z1 is defined as a circular region within a prescribed distance from the center of the ceramic plate 12. The central region C is positioned at the center of the inside zone Z1. The outside zone Z2 is defined as an annular region outside the inside zone Z1. The outside zone Z2 may be divided into a plurality of outside subzones (e.g., into two to four sections). For example, the outside zone Z2 may be composed of the plurality of outside subzones sectioned into arc shapes (e.g., into two to four sections). Alternatively, the outside zone Z2 may concentrically have two or more annular regions that have different sizes and do not overlap with each other. In that situation, the outside zone Z2 has at least a first outside zone being in proximity to the inside zone Z1 and a second outside zone positioned outside the first outside zone. If necessary, a third or more outside zones may be present outside the second outside zone; however, the ceramic heater 10 of the present invention may be a one-zone heater.

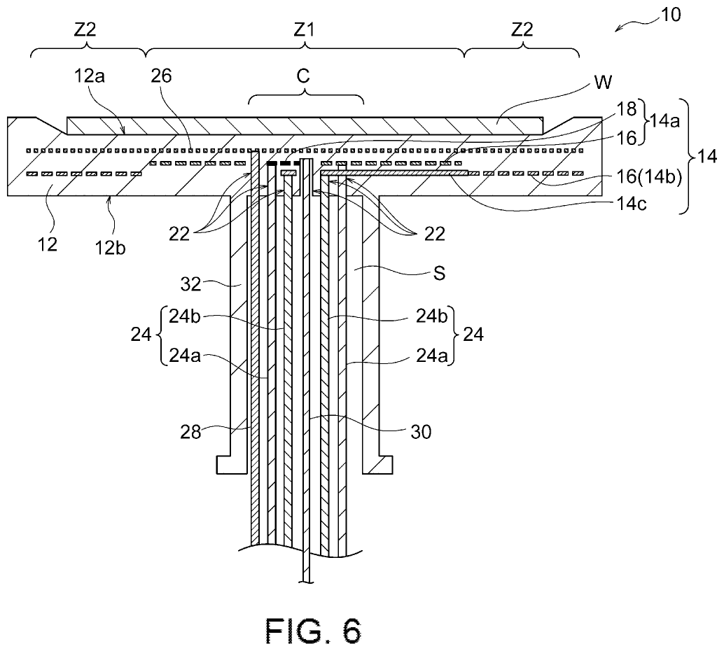

In an example of a multi-zone heater (e.g., a two-zone heater), it is desirable that the heater circuit 14 includes, as shown in FIGS. 1 and 2, the inside zone heater circuit 14a, the outside zone heater circuit 14b, and a pair of jumpers 14c. The inside zone heater circuit 14a is embedded in the inside zone Z1 of the ceramic plate 12; however, the inside zone heater circuit 14a may expand not only in the inside zone Z1, but also in the outside zone Z2. The outside zone heater circuit 14b is embedded in the outside zone Z2 of the ceramic plate 12; however, the outside zone heater circuit 14b may expand not only in the outside zone Z2, but also in the inside zone Z1. Accordingly, the inside zone heater circuit 14a and the outside zone heater circuit 14b may overlap with each other in a planar perspective view of the ceramic plate 12. The pair of jumpers 14c are embedded in the inside zone Z1 of the ceramic plate 12 so as not to be in contact with the inside zone heater circuit 14a and are electrically connected to the outside zone heater circuit 14b. The inside zone heater circuit 14a includes the heater main portion 16 and the heater element wire portion 18. The outside zone heater circuit 14b includes the heater main portion 16. In a planar perspective view of the ceramic plate 12, the heater element wire portion 18 is disposed so as not to intersect the pair of jumpers 14c. As shown in FIG. 1, the inside zone heater circuit 14a and the outside zone heater circuit 14b may be arranged on the same plane in a cross-sectional view. Alternatively, as shown in FIG. 6, the inside zone heater circuit 14a and the outside zone heater circuit 14b may be arranged on different planes in a cross-sectional view. It is desirable that the inside zone heater circuit 14a and the outside zone heater circuit 14b are each arranged in the form of a single uninterrupted line in a planar perspective view. The form of the single uninterrupted line may be any of various publicly-known forms, such as a form in which advancing and folding back repeatedly alternate or a swirl.

The inside zone heater circuit 14a may be embedded at least in the inside zone Z1 of the ceramic plate 12 while being positioned parallel to the first surface 12a. The inside zone Z1 (the central region C, in particular) of the ceramic plate 12 may be provided with a pair of first heater terminals 24a for feeding electric power to the inside zone heater circuit 14a. Preferably, the first heater terminal 24a may be connected to each of the two ends of the inside zone heater circuit 14a. There may be two or more pairs of first heater terminals 24a. The first heater terminals 24a are each in a rod form. The inside zone heater circuit 14a is connected to a heater power source (not shown) via the first heater terminals 24a in the rod form.

The outside zone heater circuit 14b may be embedded in the outside zone Z2 of the ceramic plate 12, while being positioned parallel to the first surface 12a at a depth position that is the same as or different from that of the inside zone heater circuit 14a. In a preferred aspect of the present invention, as shown in FIG. 1, the outside zone heater circuit 14b may be embedded in the outside zone Z2 of the ceramic plate 12 while being positioned parallel to the first surface 12a at the same depth position as that of the inside zone heater circuit 14a. In another preferred aspect of the present invention, as shown in FIG. 6, the outside zone heater circuit 14b may be embedded in the outside zone Z2 of the ceramic plate 12 while being positioned parallel to the first surface 12a at a different depth position from that of the inside zone heater circuit 14a. In FIG. 6, the inside zone heater circuit 14a is embedded to be higher (i.e., at a depth position closer to the first surface 12a) than the outside zone heater circuit 14b; however, possible configurations are not limited to this example. Thus, the inside zone heater circuit 14a may be embedded to be lower (i.e., at a depth position closer to the second surface 12b) than the outside zone heater circuit 14b. In either of these aspects, the inside zone Z1 (in particular, in different positions from the first heater terminals 24a within the central region C) of the ceramic plate 12 is provided with a pair of second heater terminals 24b for feeding electric power to the outside zone heater circuit 14b via the jumpers 14c. In other words, because the pair of second heater terminals 24b are positioned distant from the outside zone heater circuit 14b, the pair of second heater terminals 24b are electrically connected to the outside zone heater circuit 14b via the pair of jumpers 14c. There may be two or more pairs of second heater terminals 24b. The second heater terminals 24b are each in a rod form. The outside zone heater circuit 14b is connected to a heater power source (not shown) via the jumpers 14c and the second heater terminals 24b in the rod form.

The outside zone heater circuit 14b may be a series circuit or a parallel circuit. In other words, when forming a series circuit, the outside zone heater circuit 14b may be provided so as to start from one of the pair of jumpers 14c in one direction and to reach the other of the pair of jumpers 14c in the manner of a single uninterrupted line. Alternatively, when forming a parallel circuit, the outside zone heater circuit 14b may be provided so as to start from one of the pair of jumpers 14c in two directions and to reach the other of the pair of jumpers 14c in the manner of a single uninterrupted line with respect to each starting direction.

The pair of jumpers 14c are embedded in the inside zone Z1 of the ceramic plate 12 so as not to be in contact with the inside zone heater circuit 14a and are electrically connected to the outside zone heater circuit 14b. The pair of jumpers 14c may be embedded, while being positioned parallel to the first surface 12a, at a depth position that is the same as or different from that of the outside zone heater circuit 14b. The pair of jumpers 14c are separate from each other. One of the jumpers 14c electrically connects one of the second heater terminals 24b to one end of the outside zone heater circuit 14b, whereas the other jumper 14c electrically connects the other of the second heater terminals 24b to the other end of the outside zone heater circuit 14b. There may be two or more pairs of jumpers 14c.

Preferably, the jumpers 14c include a resistive heating element in at least one form selected from the group consisting of a line, a printed pattern, and a ribbon. Although the specific form of the line is not particularly limited, typical examples include a straight line, a curved line (e.g., an arc), and a combination of a straight line and a curved line (e.g., a straight line that is partially bent with a curvature). In a preferred aspect of the present invention, the jumpers 14c are linear resistive heating elements (i.e., resistive heating element wires).

In a planar view of the ceramic plate 12, it is desirable that the pair of jumpers 14c and the pair of second heater terminals 24b are arranged so as to be symmetrical with respect to the perpendicular bisector of a line segment connecting the pair of second heater terminals 24b together. With this configuration, it is possible to make equal the lengths of power feeding paths from the pair of second heater terminals 24b to the outside zone heater circuit 14b via the pair of jumpers 14c and to thus realize excellent temperature uniformity even more easily.

The bottomed holes 22 are non-penetrating holes formed from the second surface 12b in the thickness direction of the ceramic plate 12, so that at least a part of each of the bottomed holes 22 is positioned within the central region C of the ceramic plate 12. Thus, needless to say, the entirety of the bottomed holes 22 may be accommodated in the central region C of the ceramic plate 12. Alternatively, only a part of the bottomed holes 22 may be positioned in the central region C, while the remaining part of the bottomed holes 22 is spilling out of the central region C. The quantity of the bottomed holes 22 is four or more. Examples of the bottomed holes 22 include terminal holes for the heater terminals 24, a terminal hole for the RF terminal 28, a thermocouple hole for having the thermocouple 30 inserted, and a vacuum chuck hole for fixing the wafer W toward the first surface 12a with vacuum suction, and the like. At least two of the four or more bottomed holes 22 are the holes for the heater terminals 24. In other words, into at least two of the bottomed holes 22, at least one pair of heater terminals 24 are inserted so as to be electrically connected to the heater circuit 14. As shown in FIGS. 1 and 6, in order to accurately measure and control the temperature of the ceramic plate 12, it is desirable to have the thermocouple 30 inserted into one of the bottomed holes 22 other than the bottomed holes 22 in which the pair of heater terminals 24 are to be inserted. Accordingly, the diameter of each of the bottomed holes 22 may be determined as appropriate in accordance with the diameter of the member to be inserted such as a terminal, a thermocouple, or the like. In any case, when four or more bottomed holes 22 are present in the central region C, because the holes are concentrated in the central region C, it is difficult to arrange resistive heating elements throughout the central region C in a conventional heater circuit. In this regard, according to the present invention, it is possible to effectively solve this problem, by disposing the heater element wire portion 18 in the central region C.

The ceramic plate 12 may further include, on the inside thereof, an RF electrode 26 and/or an ESC electrode. In that situation, it is desirable to have the RF electrode 26 and/or the ESC electrode embedded in the ceramic plate 12 at a depth position closer to the first surface 12a relative to the heater circuit 14. When a radio frequency is applied thereto, the RF electrode makes it possible to perform film formation using a plasma CVD process. The ESC electrode is an abbreviation for an Electrostatic Chuck (ESC) electrode and may also be referred to as an electrostatic electrode. The ESC electrode is configured, when voltage is applied thereto from an external power source, to chuck a wafer placed on a surface of the ceramic plate 12 with Johnsen-Rahbek force. The ESC electrode may preferably be a circular thin-layer electrode which has a diameter slightly smaller than that of the ceramic plate 12 and may be, for example, a mesh-like electrode obtained by weaving a fine metal wire into a sheet form like net. The ESC electrode may also be used as a plasma electrode. In other words, by applying a radio frequency to the ESC electrode, it is also possible to use the ESC electrode as an RF electrode and to thus perform film formation using a plasma CVD process. To the RF electrode 26 or the ESC electrode, the RF terminal 28 or an ESC terminal for feeding electric power is connected. The RF terminal 28 or the ESC terminal is in a rod form, and the RF electrode 26 or the ESC electrode is connected to an external power source (not shown) via the RF terminal 28 or ESC terminal in the rod form. It is desirable that the RF terminal 28 and/or the ESC terminal is inserted into at least one of the bottomed holes 22 other than the bottomed holes 22 in which the pair of heater terminals 24 are to be inserted.

A ceramic shaft 32 may optionally be attached to the second surface 12b of the ceramic plate 12. The ceramic shaft 32 is a circular cylindrical member including an internal space S and may have a configuration that is the same as or similar to that of a ceramic shaft adopted in a publicly-known ceramic susceptor or a ceramic heater. The internal space S is configured so that the heater terminals 24, the RF terminal 28, the thermocouple 30, and the like pass therethrough. It is desirable that the ceramic shaft 32 is composed of a ceramic material that is the same as or similar to that of the ceramic plate 12. Accordingly, the ceramic shaft 32 may preferably contain aluminum nitride or aluminum oxide, and more preferably, may contain aluminum nitride. It is desirable that the upper end face of the ceramic shaft 32 is bonded to the second surface 12b of the ceramic plate 12 by solid phase bonding or diffusion bonding. Although not particularly limited, it is desirable that the outside diameter of the ceramic shaft 32 is in the range of 40 mm to 60 mm. Although not particularly limited either, it is desirable that the inside diameter of the ceramic shaft 32 (the diameter of the internal space S) is in the range of 33 mm to 55 mm. While the central region C is defined as a region within a radius of 25 mm (i.e., within a diameter of 50 mm) from the center of the ceramic plate 12, when the inside diameter (which may be referred to as an inside diameter D) of the ceramic shaft 32 is smaller than 50 mm, the central region C is defined as a region within a radius of D/2 from the center of the ceramic plate 12.

### EXAMPLES

The present invention will be explained more specifically by using the following examples; however, the present invention is not limited to the following examples.

### Example 1

### (1) Producing Ceramic Heater

By using the following constituent members, a ceramic heater 10 having the structure shown in FIGS. 1 to 4 was produced according to a publicly-known procedure except for firing conditions thereof.

### <Constituent Members and Specifications Thereof>

The ceramic plate 12: A disk-shaped sintered body of aluminum nitride (diameter: 330 mm; thickness 20 mm) (in which the inside zone heater circuit 14a, the outside zone heater circuit 14b, the jumpers 14c, and the RF electrode 26 were embedded inside);
The ceramic shaft 32: A circular cylindrical aluminum nitride sintered body (height: 172 mm; outside diameter 42 mm, and inside diameter 36 mm);
The inside zone Z1: A circular region having a diameter of 216 mm positioned at the center of the ceramic plate 12;
The outside zone Z2: An annular region outside the inside zone Z1 of the ceramic plate 12;
The inside zone heater circuit 14a: A circuit which was embedded at a depth of 6.5 mm from the first surface 12a in the inside zone Z1 according to a prescribed circuit pattern and in which the heater main portion 16 (material: molybdenum; winding diameter 3.5 mm; and wire diameter 0.5 mm) composed of a resistive heating element in a three-dimensional coil form was connected, by the connection terminal 20, to the heater element wire portion 18 composed of a non-coiled simple resistive heating wire (material: molybdenum; wire diameter 0.4 mm; disposed in the central region C of the ceramic plate 12);
The outside zone heater circuit 14b: The heater main portion 16 (material: molybdenum; winding diameter: 3.5 mm; and wire diameter 0.5 mm) composed of a resistive heating element in a three-dimensional coil form embedded at a depth of 6.5 mm from the first surface 12a in the outside zone Z2 according to a prescribed circuit pattern;
The jumpers 14c: A pair of substantially linear resistive heating wires (material: molybdenum; wire diameter: 0.7 mm) which were bilaterally symmetrical and were embedded at a depth of 6.5 mm from the first surface 12a in the inside zone Z1, so as to be embedded according to the circuit pattern shown in FIG. 3 (As shown in FIG. 3, the substantially linear shape partially includes a curved line portion);
The connection terminal 20: A spherical member made of molybdenum and having the shape shown in FIG. 5 (diameter: 3 mm; diameter of the larger through hole 20a: 0.55 mm (larger than the wire diameter of the heater main portion 16 by at most 0.05 mm); diameter of the smaller through hole 20a: 0.42 mm (larger than the wire diameter of the heater element wire portion 18 by 0.02 mm));
The bottomed holes 22: Six are provided in the central region C of the ceramic plate 12 (four bottomed holes 22 for the heater terminals 24; one bottomed hole 22 for the RF terminal 28; and one bottomed hole 22 for the thermocouple 30);
The first heater terminals 24a: Two terminal rods made of nickel;
The second heater terminals 24b: Two terminal rods made of nickel;
The RF electrode 26: An electrode layer made of molybdenum and embedded at a depth of 1.0 mm from the first surface 12a of the ceramic plate 12; and
The RF terminal 28: One terminal rod made of nickel.

The ceramic plate 12 described above in which the inside zone heater circuit 14a, the outside zone heater circuit 14b, the jumpers 14c, and the RF electrode 26 were embedded inside was produced with the following procedure. To begin with, aluminum nitride powder was press-molded to obtain a first aluminum nitride powder compact. By arranging aluminum nitride powder, the inside zone heater circuit 14a, the outside zone heater circuit 14b, and the jumpers 14c according to a prescribed circuit pattern on the obtained first aluminum nitride powder compact and press-molding, a second aluminum nitride powder compact was obtained in which the inside zone heater circuit 14a, the outside zone heater circuit 14b, and the jumpers 14c were embedded inside. By arranging aluminum nitride powder and the RF electrode 26 on the obtained second aluminum nitride powder compact and press-molding, a third aluminum nitride powder compact was obtained in which the RF electrode 26 was further embedded inside. In this manner, as shown in FIG. 1, a press-molded body composed of an aluminum nitride powder compact was obtained in which the inside zone heater circuit 14a, the outside zone heater circuit 14b, the jumpers 14c, and the RF electrode 26 were embedded. The obtained press-molded body (a laminated body) was fired under the following firing conditions in an atmosphere of nitrogen, to obtain the ceramic plate 12 in which the inside zone heater circuit 14a, the outside zone heater circuit 14b, the jumpers 14c, and the RF electrode 26 were embedded inside:
The maximum temperature: 1810° C.;
The time period held at the maximum temperature: 5 hours;
The temperature increasing rate: Varied within the range of 10° C./min to 120° C./min (which was a temperature range that included the temperature increasing rate at each of a plurality of temperature increasing stages); and
The firing pressure: 90 kg/cm².

### (2) Evaluations

The following evaluations were made on the obtained ceramic heater.

### <Temperature Uniformity>

The ceramic heater 10 was installed in a chamber of a film formation device. The chamber was evacuated and N₂ gas was introduced therein, so that the N₂ gas pressure in the chamber was 5 Torr. By feeding electric power to the inside zone heater circuit 14a and the outside zone heater circuit 14b via the first heater terminals 24a, the second heater terminals 24b, and the jumpers 14c, the ceramic heater 10 was heated to a setting temperature of 650° C. At that time, a fine adjustment was made so as to achieve the most uniform temperature distribution, while setting the ratio between the electric power supplied to the outside zone heater circuit 14b and the electric power supplied to the inside zone heater circuit 14a to 1:1 as a reference level. At that setting temperature, a temperature distribution was measured on the first surface 12a of the ceramic plate 12 by using an infrared camera. FIG. 9 presents a temperature distribution map in a region having a diameter of 300 mm and including the central region C corresponding to FIG. 3. On the basis of the obtained temperature distribution map, the difference between a maximum temperature and a minimum temperature (i.e., a maximum in-plane temperature difference) in the region having the diameter of 300 mm was calculated as an index for temperature uniformity. The results are shown in Table 1. In the present example, by disposing the heater element wire portion 18 in the central region C where the six bottomed holes 22 are concentrated, it was possible to realize sufficient heating in the central region C and to eliminate a cool spot, which would otherwise occur in the central part, as shown in FIG. 9. The reason was, because the resistive heating wire serving as the heater element wire portion 18, which was not a coil, had a width of 1 mm or smaller, that it was possible to dispose the heater element wire portion 18 so as to meander and reach the one end of the heater main portion 16 while avoiding or bypassing all the bottomed holes 22 other than the bottomed hole 22 serving as a starting point, as shown in FIG. 3.

### Example 2 (Comparison)

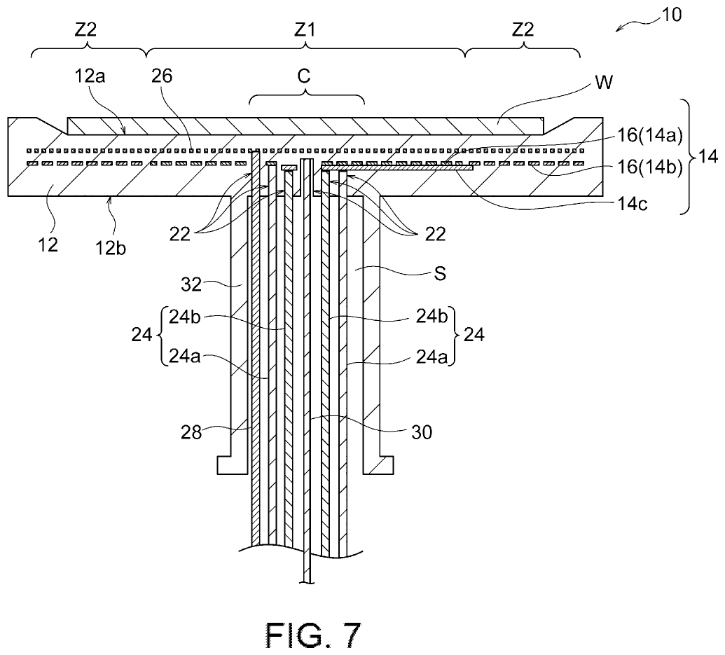

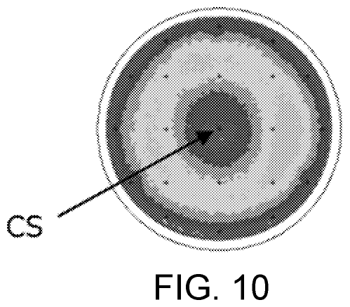

As shown in FIGS. 7 and 8, another ceramic heater was produced and evaluated similarly to Example 1, except that the heater element wire portion 18 was not disposed in the central region C of the ceramic plate 12 (i.e., the inside zone heater circuit 14a was composed only of the heater main portion 16). FIG. 10 presents a temperature distribution map in a region having a diameter of 300 mm and including the central region C corresponding to FIG. 8. On the basis of the obtained temperature distribution map, the difference between a maximum temperature and a minimum temperature (i.e., a maximum in-plane temperature difference) in the region having the diameter of 300 mm was calculated as an index for temperature uniformity. The results are shown in Table 1. In the present example, because the heater circuit 14 was not present in the central region C (i.e., there was no space for arranging the coil-shaped heater main portion 16), it was not possible to perform sufficient heating in the central region C, and a cool spot CS occurred in a central part as shown in FIG. 10.

TABLE 1

| | | Example 2 |
|---|---|---|
| | Example 1 | (Comparison) |
| Diagram of heater circuit pattern | FIG. 3 | FIG. 8 |
| arranged in central region C | | |
| Temperature distribution map of | FIG. 9 | FIG. 10 |
| region having diameter of 300 mm | | |
| (Setting temperature: 650 °C) | | |
| In-plane maximum temperature | 3.3 | 5.5 |
| difference in region having | | |
| diameter of 300 mm (°C) | | |
| Occurrence of cool spot CS in | Absent | Present |
| central region C | | |

What is claimed is:

1. A ceramic heater comprising:
a disk-shaped ceramic plate having a diameter of 220 mm or larger and having a first surface on which a wafer is to be placed and a second surface opposite the first surface;
at least one heater circuit embedded in the ceramic plate;
four or more bottomed holes provided from the second surface in a thickness direction of the ceramic plate, so that at least a part of each of the bottomed holes is positioned within a central region having a radius of 25 mm from a center of the ceramic plate; and
at least one pair of heater terminals inserted into at least two of the bottomed holes and electrically connected to the heater circuit, wherein
the heater circuit includes:
a heater main portion disposed so as to be capable of heating a region outside the central region and including a resistive heating element in at least one form selected from the group consisting of a coil, a linear zigzag structure, a printed pattern, a ribbon, and a mesh; and
a heater element wire portion disposed so as to be capable of heating the central region and composed of a non-coiled wire-shaped resistive heating element, the heater element wire portion being disposed, in a planar perspective view, so as to start from one of the heater terminals and to reach one end of the heater main portion while, within the central region, avoiding or bypassing all the bottomed holes other than the bottomed hole in which the one of the heater terminals is positioned.

2. The ceramic heater according to claim 1, wherein the wire-shaped resistive heating element has a diameter in a range of 0.3 mm to 0.8 mm.

3. The ceramic heater according to claim 1, wherein, in a planar view of the ceramic plate, the ceramic plate includes an inside zone defined as a circular region within a prescribed distance from the center of the ceramic plate; and an outside zone defined as an annular region outside the inside zone,
wherein the heater circuit includes:
an inside zone heater circuit embedded in the inside zone of the ceramic plate;
an outside zone heater circuit embedded in the outside zone of the ceramic plate; and
a pair of jumpers that are embedded in the inside zone of the ceramic plate so as not to be in contact with the inside zone heater circuit and that are electrically connected to the outside zone heater circuit, and
wherein the inside zone heater circuit includes the heater main portion and the heater element wire portion, the outside zone heater circuit includes the heater main portion, and the heater element wire portion is disposed, in a planar perspective view, so as not to intersect the pair of jumpers.

4. The ceramic heater according to claim 1, wherein the ceramic plate contains aluminum nitride or aluminum oxide.

5. The ceramic heater according to claim 1, further comprising a ceramic shaft that has a circular cylindrical shape including an internal space and is attached to the second surface of the ceramic plate.

6. The ceramic heater according to claim 1, wherein the resistive heating element contains at least one selected from the group consisting of tungsten, molybdenum, a tungsten-molybdenum alloy, tungsten carbide, a tungsten carbide titanium nitride composite material, a tungsten carbide aluminum oxide composite material, and niobium.

7. The ceramic heater according to claim 1, wherein the heater main portion and the heater element wire portion are configured as a continuous integrally-formed resistive heating element.

8. The ceramic heater according to claim 1, wherein the heater main portion and the heater element wire portion are separate resistive heating elements and are connected to each other via a connection terminal.

9. The ceramic heater according to claim 8, wherein the connection terminal is arranged within the central region of the ceramic plate.

10. The ceramic heater according to claim 1, wherein the connection terminal is a conductive member having two through holes with different diameters into which resistive heating elements having different wire diameters are connectable.

11. The ceramic heater according to claim 1, further comprising, in the ceramic plate, an internal electrode being an RF electrode and/or an ESC electrode, wherein the RF terminal and/or the ESC terminal is inserted into at least one of the bottomed holes other than the bottomed holes into which the pair of heater terminals are inserted.

12. The ceramic heater according to claim 1, wherein a thermocouple is inserted into one of the bottomed holes other than the bottomed holes into which the pair of heater terminals are inserted.

13. The ceramic heater according to claim 3, wherein the inside zone heater circuit and the outside zone heater circuit are arranged on the same plane in a cross-sectional view.

14. The ceramic heater according to claim 3, wherein the inside zone heater circuit and the outside zone heater circuit are arranged on different planes in a cross-sectional view.

15. The ceramic heater according to claim 1, wherein, when an inscribed circle in contact with all of the bottomed holes located at positions other than the center of the central region is defined, the heater element wire portion is arranged so as to extend approximately one turn in an annular region between the inscribed circle and the bottomed hole located at the center of the central region.

16. The ceramic heater according to claim 15, wherein the shape extending approximately one turn in the annular region includes a configuration in which the heater element wire portion starts from one of the bottomed holes as a starting point located at positions other than the center of the central region, bypasses around the bottomed hole located at the center of the central region, folds back, and passes between the bottomed hole serving as the starting point and the bottomed hole adjacent thereto.
